(19) United States
(12) Patent Application Publication
(10) Pub. No.: US 2025/0167143 A1
(43) Pub. Date: May 22, 2025

(54) POWER AMPLIFIER DIE

(71) Applicant: MACOM Technology Solutions Holdings, Inc., Lowell, MA (US)

(72) Inventors: Lei Zhao, Chandler, AZ (US); Bernard Stocklingsky, Tempe, AZ (US); Damon Holmes, Scottsdale, AZ (US)

(21) Appl. No.: 18/514,402

(22) Filed: Nov. 20, 2023

(51) Int. Cl. H01L 23/66; H03F 1/56; H03F 3/195; H03F 3/24

(52) U.S. Cl. CPC H01L 23/66; H03F 1/565; H03F 3/195; H03F 3/245; H01L 2223/6611; H01L 2223/6655; H03F 2200/451

(57) ABSTRACT

A power amplifier die according to some embodiments includes a substrate, a transistor formed on the substrate, and an integrated passive device, IPD, formed on the substrate adjacent to the transistor. A wire bond electrically connects the transistor and the IPD on the substrate. A method of manufacturing a power amplifier die is also provided.

### FIELD

The disclosure relates to discrete power amplifier dies that include a transistor and an input match, such as an integrated passive device (IPD), on a substrate.

### BACKGROUND

As current mobile communication systems evolve and new communications systems are developed, there is continuing demand for more powerful and efficient power amplifiers that are capable of operating over broader frequency ranges. Many of these communication systems employ mobile devices and access points, such as base stations, that are battery powered. For such communication devices, more efficient power amplifiers yield longer operating times between battery charges.

Given the ever increasing demand for efficiency, the Doherty amplifier has become a popular power amplifier in mobile communication applications, especially base station applications. While relatively efficient compared to its rivals, the Doherty amplifier has a relatively limited bandwidth of operation. For example, a well-designed Doherty amplifier may provide an instantaneous bandwidth of 5 percent, which corresponds to about 100 MHz for a 2 GHz signal and is generally sufficient to support a single communication band. For example, Universal Mobile Telecommunications Systems (UMTS) devices operate in a band between 2.11 and 2.17 GHz, and thus require an instantaneous bandwidth of 60 MHz (2.17 GHZ-2.11 GHz). A Doherty amplifier can be configured to support an instantaneous bandwidth of 60 MHz for the UMTS band. Accordingly, for communication devices that only need to support a single communication band, the limited operating bandwidth of the Doherty power amplifier may not pose a problem.

However, modern communication devices are often required to support various communication standards that employ different modulation techniques over a wide range of operating radio frequencies (RFs). These standards include but are not limited to the Global System for Mobile Communications (GSM), Personal Communication Service (PCS), Universal Mobile Telecommunications Systems (UMTS), Worldwide Interoperability for Microwave Access (WiMAX), Long Term Evolution (LTE), fifth generation (5G), sixth generation (6G), and the like.

The bands of operation for these standards range from around 800 MHz to at least 20 GHz. The GSM standards employ bands ranging from around 800 MHz to 2 GHz. For example, GSM-850 uses an 824-894 MHz band, GSM-900 uses an 890-960 MHz band, GSM-1800 uses a 1310-1880 MHz band, and GSM-1900 uses an 1850-1990 MHz band. UMTS uses a 2.11-2.17 GHz band. LTE uses a 2.6-2.7 GHz band; WiMAX uses bands centered about 2.3, 2.5, 3.3 and 3.5 GHz; 5G uses a 1-6 GHz range; and 6G may use frequencies in at least the range 7-20 GHz.

Moreover, for power amplifiers targeting a cellular infrastructure market, for example, there is an ever-increasing demand for higher efficiency. Conventional amplifier architectures, however, may not be enough to meet efficiency needs.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group III nitrides (e.g., 3.36 eV for GaN at room temperature). These materials may have higher electric field breakdown strengths and higher electron saturation velocities than GaAs and Si.

A device of particular interest for high power and/or high frequency applications is the High Electron Mobility Transistor (HEMT), which is also known as a modulation doped field effect transistor (MODFET). In a HEMT device, a two-dimensional electron gas (2DEG) may be formed at the heterojunction of two semiconductor materials with different bandgap energies, where the smaller bandgap material has a higher electron affinity than the wider bandgap material. The 2DEG is an accumulation layer in the undoped smaller bandgap material and can contain a relatively high sheet electron concentration, for example, in excess of 10¹³ carriers/cm². Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide a performance advantage over metal-semiconductor field effect transistors (MESFETS) for high-frequency applications.

HEMTs fabricated in the gallium nitride/aluminum gallium nitride (GaN/AlGaN) material system can generate large amounts of RF power due to a combination of material characteristics, such as relatively high breakdown fields, relatively wide bandgaps, relatively large conduction band offset, and/or relatively high saturated electron drift velocity. A major portion of the electrons in the 2DEG may be attributed to polarization in the AlGaN.

A GaN-based HEMT can be formed on a silicon carbide (SiC) substrate. A GaN channel layer can be on the substrate of the HEMT, and an AlGaN barrier layer can be on the channel layer. A 2DEG can arise in the channel layer adjacent the barrier layer. A source contact and a drain contact can be formed on the channel layer. The conductivity of the 2DEG can be modulated by applying a voltage to a gate that can be formed on the barrier layer between the source contact and the drain contact.

Packaged transistors have been used that include a transistor (e.g., a HEMT) in a metal-based package along with discrete matching components of an input matching circuit and/or an output matching circuit between the package leads and transistor gate and drain pads. The discrete matching components of the input matching circuit and/or an output matching circuit of the package typically are used to match an impedance (e.g., 50 ohms) for a particular frequency (e.g., 3.1 GHZ) or a particular frequency range (e.g., 3.1-3.5 GHZ).

Packaged transistors also may be implemented with separate, discrete transistor die and integrated passive device (IPD) die.

### SUMMARY

A power amplifier die according to some embodiments includes a substrate, a transistor formed on the substrate, and an IPD formed on the substrate adjacent to the transistor. A wire bond electrically connects the transistor and the IPD on the substrate.

The IPD may include a capacitor.

The IPD may include at least a portion of an input match for the transistor and the wire bond may include an inductor of at least the portion of the input match.

At least a portion of the wire bond may have a height that is adjustable so as alter an inductance of the input match.

The power amplifier die may further include a portion of the substrate positioned between the transistor and the IPD.

The portion of the substrate may include an unsawn portion of the substrate (i) between the transistor and the IPD and (ii) positioned beneath the wire bond.

The unsawn portion of the substrate between the transistor and the IPD may have a width in a range between about 2 mils and less than 10 mils.

The unsawn portion of the substrate between the transistor and the IPD may have a width in a range between about 0 mils and about 2 mils.

The substrate may include a semiconductor substrate.

The substrate may include one SiC, Si, and GaAs.

The power amplifier die may be configured to operate above about 3 GHZ.

A method of manufacturing a power amplifier die is provided according to some other embodiments. The method includes providing a substrate; forming a transistor on the substrate; and forming an integrated passive device, IPD, on the substrate adjacent to the transistor with a first portion of the substrate between the transistor and the IPD and a second portion of the substrate around an outer perimeter of the transistor and the IPD. The method further includes electrically connecting the transistor and the IPD with a wire bond across the first portion of the substrate.

The first portion of the substrate between the transistor and the IPD may include a first saw street.

The second portion of the substrate around an outer perimeter of the transistor and the IPD may form a second saw street.

The IPD may include a capacitor.

The IPD may include at least a portion of an input match for the transistor and the wire bond comprises an inductor of at least the portion of the input match.

At least a portion of the wire bond may have a height that is adjustable so as alter an inductance of the input match.

The first portion of the substrate may include an unsawn portion of the substrate (i) between the transistor and the IPD and (ii) positioned beneath the wire bond.

The unsawn portion of the substrate between the transistor and the IPD may have a width in a range between about 2 mils and less than 10 mils.

The unsawn portion of the substrate between the transistor and the IPD may have a width in a range between about 0 mils and about 2 mils.

The method may further include dicing the power amplifier die along the second portion of the substrate around the outer perimeter of the transistor and the IPD.

The substrate may include a semiconductor substrate.

The substrate may include one of SiC, Si, and GaAs.

The power amplifier die may be configured to operate above about 3 GHz.

Additional features, advantages, and aspects of the disclosure may be set forth or apparent from consideration of the following detailed description, drawings, and claims. Moreover, it is to be understood that both the foregoing summary of the disclosure and the following detailed description includes examples and are intended to provide further explanation without limiting the scope of the disclosure as claimed.

### BRIEF DESCRIPTION OF THE DRAWINGS

The accompanying drawings, which are included to provide a further understanding of the disclosure, are incorporated in, and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a schematic diagram showing an example of a multi-stage impedance matching network for an amplifier.

FIG. 2 is a schematic diagram of an example of a discrete transistor die and a discrete IPD connected via wire bonds.

FIG. 3A is a schematic diagram showing a top view of an example embodiment of a power amplifier die that includes a transistor die and an IPD die that are not sawed apart according to some embodiments.

FIGS. 3B-3D are schematic diagrams showing three example embodiments of a power amplifier die that includes a wire bond having different heights according to some embodiments.

FIG. 4A is a schematic diagram showing an example embodiment of a wafer that includes transistor dies, IPD dies, and first and second saw streets according to some embodiments.

FIGS. 4B and 4C are schematic diagrams of other example embodiments of a wafer that includes transistor dies, IPD dies, and first and second saw streets according to some embodiments.

FIG. 5 is a flowchart of a method of manufacturing a power amplifier die according to some embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Some approaches may implement a harmonic match on the input of a transistor to try to improve the efficiency of a power amplifier beyond what a conventional Doherty architecture may achieve.

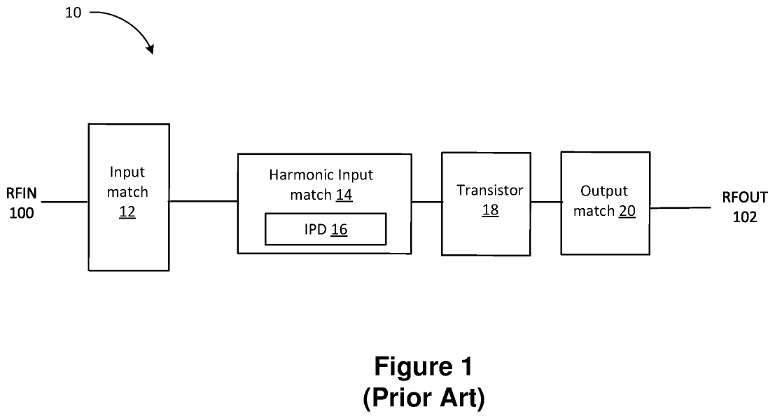

For example, FIG. 1 is a schematic diagram showing a multi-stage impedance matching network 10 for an amplifier. As illustrated in FIG. 1, a modulated RF input signal RF_{IN} 100 is fed to an input match circuit 12. The input match circuit 12 can include a phase shifter, such as a transmission line or a lumped element network of a transmission line with a certain cut-off frequency. A lumped element network is one that can include inductors, capacitors, and/or resistors as the primary filtering and phase shifting components.

The output of the input match circuit 12 is fed to second harmonic input match circuit 14. Second harmonic input match circuit 14 may be a high-pass type impedance matching network using an IPD 16 that include a shunt capacitor, for example.

The output of the second harmonic input match circuit 14 is provided to the input of transistor 18 which amplifies the RF signal. An output matching network 20 is coupled to the output of transistor 18. A function of the output match network 20 is to remove phase shifts provided by the input match circuit 12 and provide any phase offset deemed necessary to try to achieve desired performance metrics. After passing through the output match network 20, the amplified RF input signal is output (RFOUT 101).

The output match component 20 may be, for example, a transmission line that introduces a phase shift and provides an impedance match. Output match component 20 may be lumped circuit elements in place of a transmission line, for example.

The multi-stage impedance matching network of FIG. 1 has a characteristic operational frequency range, and its performance may degrade beyond this frequency range.

Design challenges for multi-stage impedance matching networks, such as the matching network 10 shown in FIG. 1, may include that the input match is not tunable.

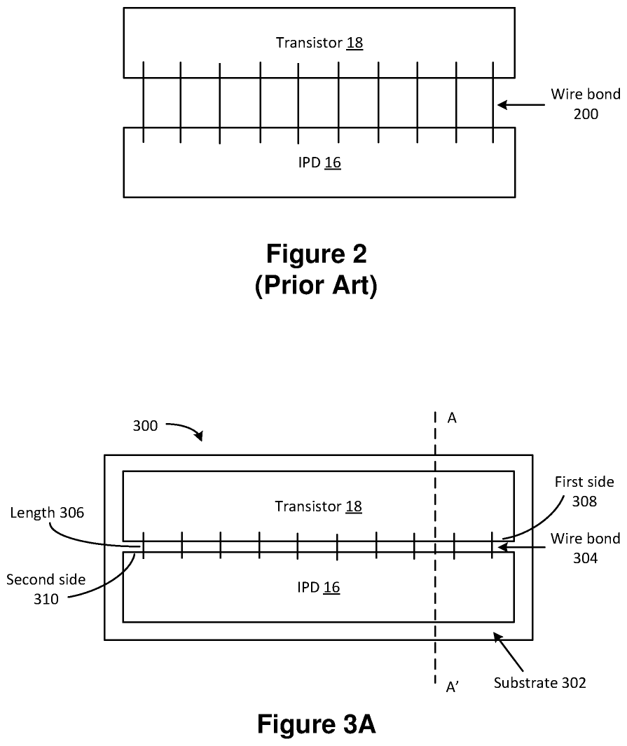

In another approach, RF power amplifiers may use separate, discrete die for respective transistors and passive components (e.g., IPDs) inside a package. FIG. 2 is a schematic diagram of an example of a discrete transistor die 18 and a discrete IPD 16 connected via wire bonds 200. To make FIG. 2 less complicated, the package that includes the discrete transistor die 18 and IPD 16 is not shown.

Some other approaches may include integrated power amplifiers. For example, packaged transistors may be implemented as monolithic microwave integrated circuits (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. Typically, however, a custom fabrication process is needed for an integrated design that can take months and, upon completion, the design is inflexible (e.g., the input match is not tunable).

In comparison to a MMIC, power amplifiers that include discrete components, such as in the example shown in FIG. 2, may offer design flexibility and faster manufacturing cycle time since individual, standard transistors and individual passive components (e.g., IPD 16) may be readily available for use after they have been diced and separated on a wafer. The assembling of multiple, discrete components in production, however, adds manufacturing complexity. As a consequence, manufacturing design rules may limit design feasibility and achievable RF performance. For example, for a dual-flat no-leads (DFN) package, the separation between two adjacent dies on a wafer may need to be at least 10 mils and the lowest loop height of a bond wire may need to be at least 10 mil. While such design rule restrictions may not pose an issue for implementing a harmonic input match at below 3 GHz, for example, such design rule restrictions may result in an inductance that is too high for designs above 3 GHz. Such a high inductance, for example, may make a harmonic input match impossible.

One approach to try to address such an issue may be to layout the harmonic input matching circuit on the transistor die. While this approach may achieve an optimum design in terms of RF performance, this approach may make the transistor die a custom layout that may not be used in other designs targeting different power levels or frequencies. The die also may not be readily available as it may have to go through a long fabrication cycle.

Thus, there is a need for higher-efficiency power amplifiers for applications above about 3 GHZ, for example.

The present disclosure relates to power amplifier dies that include transistor and capacitor dies that are not sawn apart which may achieve efficiency improvement in a discrete power amplifier operating above 3 GHZ, for example.

Some examples include, during manufacturing, to layout a transistor and an input IPD (e.g., including a capacitor) next to each other on a mask as individual dies with a saw street in between. The two dies can be sawed apart to be available as standard components for other discrete designs. For designs that need to implement a harmonic input match at above about 3 GHz to meet an efficiency need, for example, the two dies are not sawed apart and are used as a single die. In some examples, the saw street is 2 mil wide and, as a consequence, the wire bonds connecting the transistor and the IPD may be significantly shorter than in conventional designs. As a consequence, the shorter wire bonds may result in lower inductance (e.g., significantly lower) and efficiency improvement for designs above about 3 GHz, for example.

Conventional approaches include that individual dies on a finished wafer (e.g., a SiC wafer), for active and/or passive components, are singulated after dicing of the wafer. Each wafer may be sawed along saw streets to obtain the individual dies.

In contrast, as shown in FIG. 4A, in some examples of the present disclosure, by laying out, on a wafer 400, the transistor die 18 and the IPD 16 next to each for an input harmonic match and not sawing them apart, the wire bonds connecting them, which function as an inductor in the input matching circuit, may be significantly shorter than wire bonds would be if the transistor die 18 and the IPD were separate. As a consequence, the inductance needed to implement an input harmonic match at above about 3 GHz may be achieved.

Moreover, if needed, the transistor die 18 and the IPD 16 also may be sawed apart and be available as standard components for other discrete designs operating at different power levels and/or frequencies. FIG. 2, for example, is an example of a conventional approach of implementing the harmonic input match by using two sawed dies 18, 16.

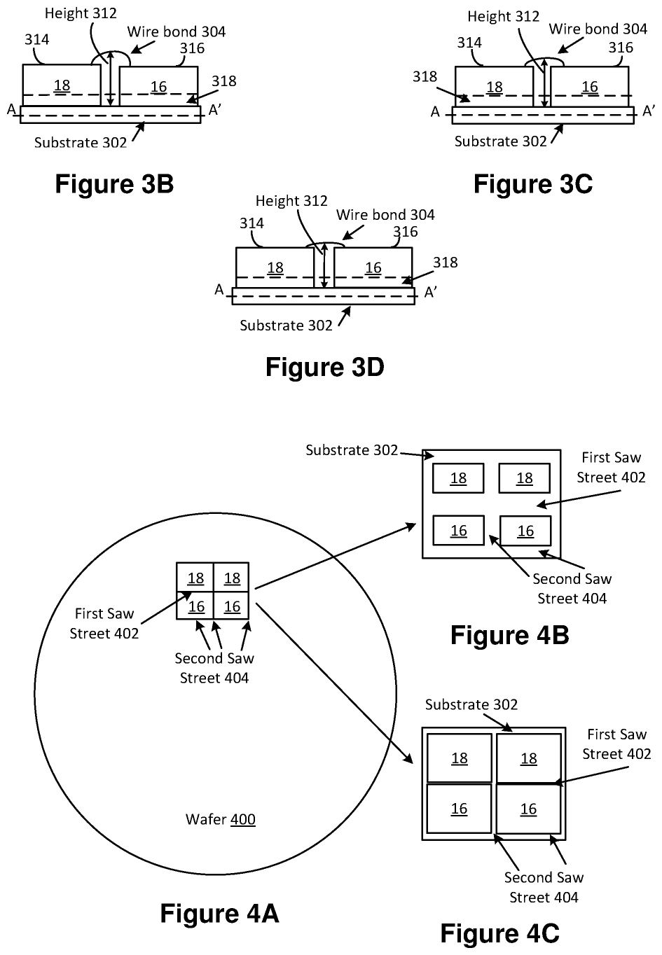

FIG. 3A is a schematic diagram showing a top view of an example embodiment of a power amplifier die 300 that includes a transistor die 18 and an IPD die 16 that are not sawed apart. The transistor die 18 and the IPD 16 are formed on a single substrate 302 (e.g., on wafer 400 as discussed further herein) and, optionally, may respectively include an epitaxial layer 318. The transistor die 18 and the IPD die 16 are connected via wire bonds 304 have a length 306. The specific length 306 of wire bond(s) 304 may be varied for each specific implementation, to control inductance of an input harmonic match for power amplifier die 300.

As shown in FIG. 3A, the length 306 of wire bond(s) 304 is shown as a length from a first side 308 of transistor 18 (e.g., from a first bond pad (not shown) for transistor die 18) to a second side 310 of IPD die 16 (e.g., to a second bond pad (not shown) for IPD die 16).

Moreover, the specific length 306 of wire bond(s) 304 may vary based on the size of the separation between the first side 306 of transistor die 18 and the second side 310 of IPD die 16.

In some embodiments, a power amplifier die is provided. The power amplifier die includes a substrate; a transistor formed on the substrate; and an IPD formed on the substrate adjacent to the transistor. The power amplifier die further includes a wire bond electrically connecting the transistor and the IPD on the substrate.

The IPD can include a capacitor. In some embodiments, the IPD includes at least a portion of an input match for the transistor and the wire bond includes an inductor of at least the portion of the input match.

At least a portion of the wire bond has a height that may be adjustable so as alter an inductance of the input match.

FIGS. 3B-3D are cross-sectional views of three examples of the power amplifier die 300 of FIG. 3A across line A-A′. The three examples in FIGS. 3B-3D differ from one another with respect to a height 312 of the wire bond(s) 304 above a top surface of the substrate 302 of the power amplifier device 300. The illustrated height 312 is greatest in FIG. 3B and less in each of the examples in FIGS. 3C and 3D. The specific height 312 of wire bond(s) 304 may be varied for each specific implementation, to control inductance of an input harmonic match for power amplifier die 300.

Moreover, while height 312 in FIGS. 3B-3D is shown as a distance between a top surface of substrate 302 in a space separating first side 308 of transistor die 18 and second side 310 of IPD die 16, the height 312 may be measured in another location along the length 306 of wire bond 304. For example, the height 312 may be a height between a top surface 314 of transistor die 18 and/or a top surface 316 IPD die 16 and the loop of wire bond 304.

In some embodiments, the power amplifier die further includes a portion of the substrate positioned between the transistor and the IPD.

The portion of the substrate may include an unsawn portion of the substrate (i) between the transistor and the IPD and (ii) positioned beneath the wire bond.

FIG. 4A shows an example of a wafer 400 on which two transistor dies 18 and two IPD dies 16 are formed. While two transistor dies 18 and two IPD dies 16 are shown for simplicity, during fabrication, many transistor die 18 and IPD die 16 are formed on and populate wafer 400.

As shown in FIG. 4A, a respective transistor die 18 and IPD die 16 are next to each other on wafer 400 as individual dies with a first saw street 402 in between the transistor dies 18 and the IPD die 16. The two dies 18, 16 can be sawed apart along the first saw street 402 and the second saw streets 404 to be available as standard components for other discrete designs.

However, in accordance with embodiments herein, for designs that need to implement a harmonic input match at above about 3 GHz, for example, the respective sets of dies 18, 16 are not sawed apart along the first saw street 402 and form one power amplifier die 300. The specific size of the first saw street 402 may be varied for each specific implementation depending on the length 306 and/or the height 312 desired for wire bond 304, to control inductance of an input harmonic match for power amplifier die 300. Moreover, the specific size of one or more of the first saw street 402 and/or second saw street(s) 404 may be varied for each specific implementation, for example, depending on manufacturing tolerances for sawing.

FIG. 4B shows a top view of another example of first saw street 402 and second saw streets 404. In this example, first saw street 402 is wider in comparison to the width of the first saw street 402 between the transistor die 18 and IPD die 16 shown in FIG. 4A. Additionally, second saw street 404 around an outer perimeter of the power amplifier die comprising the transistor die 18 and the IPD die 16 is wider in comparison to the width of the second saw street 404 shown in FIG. 4A.

FIG. 4C shows a top view of a yet another example of first saw street 402 and second saw streets 404. In this example, first saw street is narrower than the first saw street 402 shown in FIG. 4B but wider than the first saw street 402 shown in FIG. 4A. Moreover, second saw streets 404 also are narrower than saw streets 404 shown in FIG. 4B but wider than second saw street 404 shown in FIG. 4A.

Additionally, one of skill in the art will understand that first saw street 402 and second saw streets 404 may have the same or different widths.

In some embodiments, the unsawn portion of the substrate of the power amplifier die between the transistor and the IPD has a width in a range between about 2 mils and less than 10 mils.

In other embodiments, the unsawn portion of the substrate of the power amplifier die between the transistor and the IPD has a width in a range between about 0 mils and about 2 mils.

The substrate (e.g., substrate 302) of the power amplifier die may be a semiconductor substrate.

In some embodiments, the substrate of the power amplifier die includes one of SiC, Si, and GaAs.

The power amplifier die may be configured to operate above about 3 GHZ.

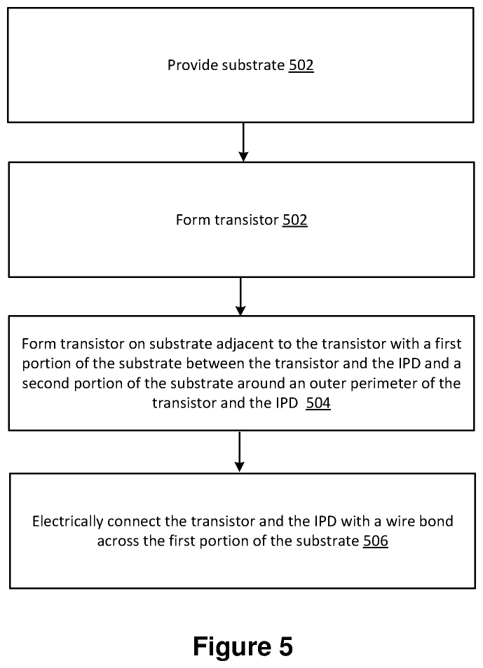

FIG. 5 is a flowchart of operations in a method 500 of manufacturing a power amplifier die. A substrate is provided (block 502). A transistor is formed on the substrate (block 504). An IPD is formed on the substrate adjacent to the transistor with a first portion of the substrate between the transistor and the IPD and a second portion of the substrate around an outer perimeter of the transistor and the IPD. A wire bond is electrically connected to the transistor and the IPD across the first portion of the substrate (block 506).

The first portion of the substrate between the transistor and the IPD may include a first saw street. The second portion of the substrate around an outer perimeter of the transistor and the IPD may form a second saw street.

The IPD may include a capacitor. The IPD may include at least a portion of an input match for the transistor and the wire bond comprises an inductor of at least the portion of the input match.

In some embodiments, at least a portion of the wire bond has a height that is adjustable so as alter an inductance of the input match.

The first portion of the substrate may include an unsawn portion of the substrate (i) between the transistor and the IPD and (ii) positioned beneath the wire bond.

In some embodiments, the unsawn portion of the substrate between the transistor and the IPD has a width in a range between about 2 mils and less than 10 mils.

In other embodiments, the unsawn portion of the substrate between the transistor and the IPD has a width in a range between about 0 mils and about 2 mils.

In some embodiments, the method further includes dicing the power amplifier die along the second portion of the substrate around the outer perimeter of the transistor and the IPD.

Embodiments of the present disclosure may be advantageously employed in any amplifier application where a transistor die is electrically connected to an IPD die on a substrate, and where control of an inductance of an input match for the transistor is advantageous. Embodiments are particularly well suited for wireless communications applications, such as for operations above about 3 GHz.

Embodiments of the present disclosure present significant advantages over the prior art. By engineering the length/height of a wire bond between a transistor and an IPD on a substrate, to achieve a required or desired inductance, the operation of the power amplifier die may be optimized, improving efficiency.

Many variations of the features of the above embodiments are possible. Transistor structures with features that may be used in embodiments of the present invention are disclosed in the following commonly assigned publications, the contents of each of which are fully incorporated by reference herein in their entirety: U.S. Pat. No. 6,849,882 to Chavarkar et al. and entitled “Group-III Nitride Based High Electron Mobility Transistor (HEMT) With Barrier/Spacer Layer”; U.S. Pat. No. 7,230,284 to Parikh et al. and entitled “Insulating Gate AlGaN/GaN HEMT”; U.S. Pat. No. 7,501,669 to Parikh et al. and entitled “Wide Bandgap Transistor Devices With Field Plates”; U.S. Pat. No. 7,126,426 to Mishra et al. and entitled “Cascode Amplifier Structures Including Wide Bandgap Field Effect Transistor With Field Plates”; U.S. Pat. No. 7,550,783 to Wu et al. and entitled “Wide Bandgap HEMTs With Source Connected Field Plates”; U.S. Pat. No. 7,573,078 to Wu et al. and entitled “Wide Bandgap Transistors With Multiple Field Plates”; U.S. Pat. Pub. No. 2005/0253167 to Wu et al. and entitled “Wide Bandgap Field Effect Transistors With Source Connected Field Plates”; U.S. Pat. Pub. No. 2006/0202272 to Wu et al. and entitled “Wide Bandgap Transistors With Gate-Source Field Plates”; U.S. Pat. Pub. No. 2008/0128752 to Wu and entitled “GaN Based HEMTs With Buried Field Plates”; U.S. Pat. Pub. No. 2010/0276698 to Moore et al. and entitled “Gate Electrodes For Millimeter-Wave Operation and Methods of Fabrication; U.S. Pat. Pub. No. 2012/0049973 to Smith, Jr. et al. and entitled “High Power Gallium Nitride Field Effect Transistor Switches”; U.S. Pat. Pub. No. 2012/0194276 to Fisher and entitled “Low Noise Amplifiers Including Group III Nitride Based High Electron Mobility Transistors”; and U.S. Pat. No. 9,847,411 to Sriram et al. entitled “Recessed field plate transistor structures.”

Although embodiments of the inventive concepts have been described in considerable detail with reference to certain configurations thereof, other versions are possible. The power amplifier die can also have many different configurations. Accordingly, the spirit and scope of the invention should not be limited to the specific embodiments described above.

What is claimed is:

1. A power amplifier die, comprising:
a substrate;
a transistor formed on the substrate;
an integrated passive device, IPD, formed on the substrate adjacent to the transistor; and
a wire bond electrically connecting the transistor and the IPD on the substrate.

2. The power amplifier die of claim 1, wherein the IPD comprises a capacitor.

3. The power amplifier die of claim 1, wherein the IPD comprises at least a portion of an input match for the transistor and the wire bond comprises an inductor of at least the portion of the input match.

4. The power amplifier die of claim 3, wherein at least a portion of the wire bond has a height that is adjustable so as alter an inductance of the input match.

5. The power amplifier die of claim 1, further comprising:
a portion of the substrate positioned between the transistor and the IPD.

6. The power amplifier die of claim 5, wherein the portion of the substrate comprises an unsawn portion of the substrate (i) between the transistor and the IPD and (ii) positioned beneath the wire bond.

7. The power amplifier die of claim 6, wherein the unsawn portion of the substrate between the transistor and the IPD has a width in a range between about 2 mils and less than 10 mils.

8. The power amplifier die of claim 6, wherein the unsawn portion of the substrate between the transistor and the IPD has a width in a range between about 0 mils and about 2 mils.

9. The power amplifier die of claim 1, wherein the substrate comprises a semiconductor substrate.

10. The power amplifier die of claim 1, wherein the substrate comprises one of silicon carbide (SiC), silicon (Si), and gallium arsenide (GaAs).

11. The power amplifier die of claim 1, wherein the power amplifier die is configured to operate above about 3 GHZ.

12. A method of manufacturing a power amplifier die, comprising:
providing a substrate;
forming a transistor on the substrate;
forming an integrated passive device, IPD, on the substrate adjacent to the transistor with a first portion of the substrate between the transistor and the IPD and a second portion of the substrate around an outer perimeter of the transistor and the IPD; and
electrically connecting the transistor and the IPD with a wire bond across the first portion of the substrate.

13. The method of claim 12, wherein the first portion of the substrate between the transistor and the IPD comprises a first saw street.

14. The method of claim 12, wherein the second portion of the substrate around an outer perimeter of the transistor and the IPD form a second saw street.

15. The power amplifier die of claim 1, wherein the IPD comprises a capacitor.

16. The method of claim 12, wherein the IPD comprises at least a portion of an input match for the transistor and the wire bond comprises an inductor of at least the portion of the input match.

17. The method of claim 16, wherein at least a portion of the wire bond has a height that is adjustable so as alter an inductance of the input match.

18. The method of claim 12, wherein the first portion of the substrate comprises an unsawn portion of the substrate (i) between the transistor and the IPD and (ii) positioned beneath the wire bond.

19. The method of claim 18, wherein the unsawn portion of the substrate between the transistor and the IPD has a width in a range between about 2 mils and less than 10 mils.

20. The method of claim 18, wherein the unsawn portion of the substrate between the transistor and the IPD has a width in a range between about 0 mils and about 2 mils.

21. The method of claim 12, further comprising:
dicing the power amplifier die along the second portion of the substrate around the outer perimeter of the transistor and the IPD.

22. The method of claim 12, wherein the substrate comprises a semiconductor substrate.

23. The method of claim 12, wherein the substrate comprises one of silicon carbide (SiC), silicon (Si), and gallium arsenide (GaAs).

24. The method of claim 12, wherein power amplifier die is configured to operate above about 3 GHz.
